(19) United States
(12) Patent Application Publication
(10) Pub. No.: US 2014/0035080 A1
(43) Pub. Date: Feb. 6, 2014

(54) Wafer Level Camera Module Structure

(71) Applicant: Chi-Kuei Lee, Bade City (TW)

(72) Inventor: Chi-Kuei Lee, Bade City (TW)

(73) Assignee: LARVIEW TECHNOLOGIES CORPORATION, Yangmei City (TW)

(21) Appl. No.: 13/565,612

(22) Filed: Aug. 2, 2012

(51) Int. Cl. H01L 27/146

(52) U.S. Cl. 257/432; 257/E27.13

(57) ABSTRACT

The present invention provides a wafer level camera module structure comprising a chip with a sensing area. A TSV structure is formed by passing through from the top surface to the bottom surface of the chip. A transparent material is disposed on the chip, with at least one conductive via structure formed therein and a trace form thereon. A lens holder is disposed on the transparent material, and a lens is located on the top of the lens holder. The lens is substantially aligning to the transparent material and the sensing area.

### TECHNICAL FIELD

The present invention generally relates to semiconductor device module structure, more particularly, to a wafer level camera module structure by integrating an active/passive component, a lens holder and an image sensor to reduce the device size.

### BACKGROUND

In the field of semiconductor devices, the device density is increased and the device dimension is reduced, continuously. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor chip become more complicated, the traditional package technique, for example lead frame package, flex package, rigid package technique, can't meet the demand of producing smaller chip with high density components on the chip. Wafer level package (WLP) technique is an advanced packaging technology, by which the dice are manufactured and tested on the wafer, and then the wafer is singulated by dicing for assembly in a surface-mount line. Because the wafer level package technique utilizes the whole wafer as one object, not utilizing a single chip or die, and therefore, before performing a scribing process, packaging and testing has been accomplished. Furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

A CMOS image sensor is manufactured into a CMOS image sensor module from a CMOS image sensor chip by an electronic package technology. And it is applied into various goods and a package specification required by the CMOS image sensor module depends on characteristics of the finished goods. Especially, the recent tendencies of a CMOS image sensor module, namely, high electricity capabilities, miniaturization/high density, a low power consumption, multifunction, a high speed signal processing, a reliability are the representative characteristics of a miniaturization of the electronic goods.

Currently, in wafer level package (WLP), it is possible to reduce the height of the module structure, but the active/passive components can not be configured in the module structure, and thus the active/passive components need to be configured on the outside region of the module structure. Therefore, the size of the module structure in X/Y orientation can not be reduced.

Therefore, based-on the shortcomings of prior arts, the present invention provide a newly wafer level camera module structure.

### SUMMARY OF THE INVENTION

Based-on the shortcomings of the above-mentioned, an objective of the present invention is to provide a wafer level camera module structure with a smaller height of the module structure.

Another objective of the present invention is to provide a wafer level camera module structure by integrating active/passive component into an identical module structure.

According to an aspect of the present invention, the present invention provides a wafer level camera module structure. The module structure comprises a chip with a sensing area, and a through silicon via structure formed by passing through from a top surface to a bottom surface of the chip. A transparent layer is disposed on the chip, with at least one conductive via structure formed therein, and a trace and at least one electronic component formed thereon, wherein the trace is electrically connected to the conductive via structure and the at least one electronic component, and the conductive via structure substantially aligning to the through silicon via structure. A lens holder is disposed on the transparent layer, and a lens is located on the top of the lens holder, substantially aligning to the transparent material and the sensing area.

The lens holder is adhered to the transparent layer via an adhesion layer.

In another example, the module structure further comprises a conductive layer coupled to the conductive via structure and the through silicon via structure; solder balls formed under the through silicon via structure.

The at least one electronic component comprises at least one active component or at least one passive component.

### BRIEF DESCRIPTION OF THE DRAWINGS

The components, characteristics and advantages of the present invention may be understood by the detailed descriptions of the preferred embodiments outlined in the specification and the drawings attached:

FIG. 1 illustrates a sectional view of a camera module structure by integrating a lens holder and an image sensor chip;

FIG. 2 illustrates a sectional view of a wafer level camera module structure according to an embodiment of the present invention;

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

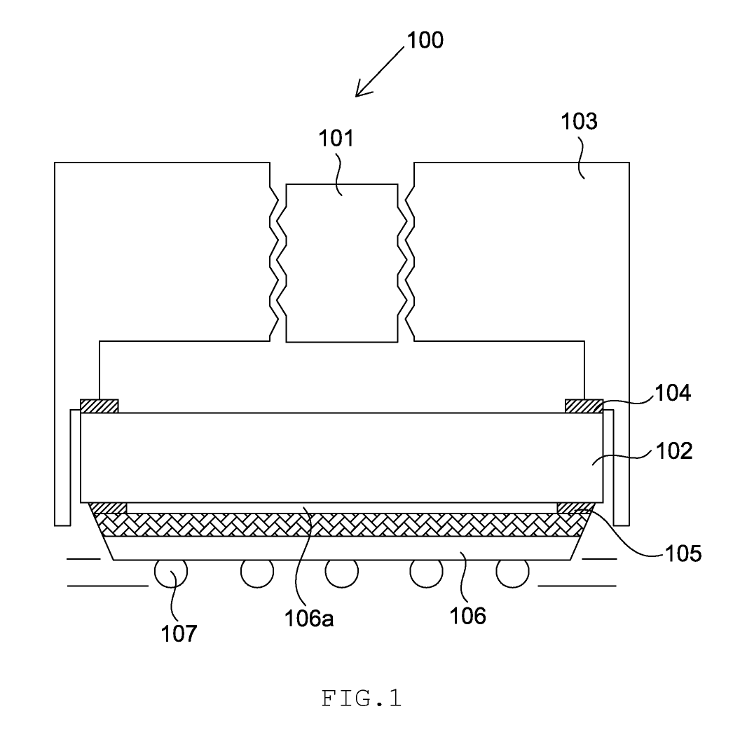

FIG. 1 shows a sectional view of a camera module structure by integrating a lens holder and an image sensor chip. As shown in FIG. 1, the camera module structure 100 integrates the lens holder and the image sensor chip to be as a module structure with sensing function, which can be applied to a camera module of a mobile phone or a portable device. The camera module structure 100 comprises a chip 106, a lens holder 103, a lens 101 and a transparent plate 102. The transparent plate 102 is located on the inner layer or the middle layer of the module, and the chip 106 is located on the bottom of the module structure.

The manufacturing process for the module structure 100 is described as follow. Firstly, the transparent plate 102 is directly adhered to (on) the chip 106. In this step, an adhesion layer 105 is formed on the chip 106, and then the transparent plate 102 is adhered to (on) the chip 106 via the adhesion 105. In an example, the size of the transparent 102 is substantially the same as or larger than that of the chip 106. In one embodiment, the adhesion layer 105 may be formed as an adhesion layer pattern on the chip 106 by employing a printing or coating process. For example, the chip 106 is an image sensor chip which has a sensing area 106a on its surface and a contact pad 105 formed thereon. Solder balls 107 are formed under the chip 106 for facilitating the chip 106 of the module structure 100 electrically connecting to an external device.

The transparent plate 102 is, for example a glass substrate or the substrate made of a transparent material, located on the chip 106.

Subsequently, a holder mounting process is performed, and the lens holder 103 is adhered on the transparent plate 102 to form a module structure. In this step, an adhesion layer 104 is formed on the transparent plate 102, and then the lower portion of the lens holder 103 is adhered on the transparent plate 102 via the adhesion layer 104.

The lens 101 is fixed to the lens holder 103 for supporting the lens 101. Moreover, the lens holder 103 may be fixed to the transparent plate 102. The lens 101 may be optionally disposed above the lens holder. In the module structure 100 of this embodiment, the transparent plate 102 may be optionally disposed within a concave structure or an accommodated space of the lens holder 103, and between the lens 101 and the chip 106. In other words, the lens 101 is substantially aligning to the transparent plate 102 and the chip 106, and thereby the propagating light directly reaching to the sensing area 106a of the chip 106.

After the module structure 100 completed, alignment test for the lens 101, the transparent plate 102 and the sensing area 106a of the chip 106 is then performed, and electrical test of the image sensor chip 106.

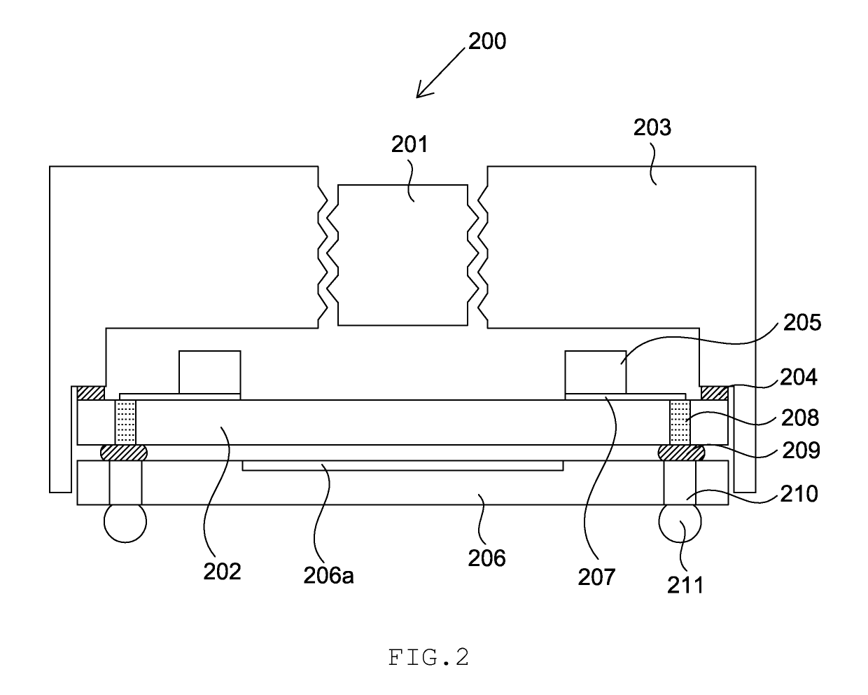

As shown in FIG. 2, it shows a sectional view of a wafer level camera module structure according to another embodiment of the present invention. In this embodiment, the wafer level camera module structure 200 can be applied to a camera module of a mobile phone or other portable devices. The wafer level camera module structure 200 comprises a chip 206, a transparent plate 202, a lens holder 203, a lens 201 and a electronic component 205. The transparent plate 202 is located on the inner layer or the middle layer of the module structure, and the chip 206 is located on the bottom of the module structure. Moreover, the electronic component 205 is located on the transparent plate 202, and the location of the configuration of the electronic component 205 is to avoid the optical path for the lens 201, and to avoid blocking light forwarding to the sensing area 206a of the chip 206.

The chip 206 is for example an image sensor die formed on the silicon wafer, which has a first through hole structure at two-sides of the chip passing through from the top surface to the bottom surface of the chip 206. A conductive material is filled into the first through hole structure to form a through silicon via (TSV) structure 210. The TSV structure 210 is pre-formed within the silicon wafer (the chip 206).

The chip 206 has a contact pad coupled to the TSV structure 210 via a trace on the chip. A conductive (metal) layer 209 may be formed (coated) on the TSV structure 210 for electrically connecting. Solder balls 211 are formed under the TSV structure 210 for facilitating the chip 206 and the electronic component 205 of the module structure 200 electrically connecting to the external component.

The transparent plate 202 has a second through hole structure formed at two-sides of the transparent plate. Another conductive material is filled into the second through hole structure to form a conductive via structure 208. The conductive via structure 208 is electrically connected to the conductive layer 209. The conductive layer 209 is electrically connected to the conductive via structure 208 and the TSV structure 210 of the chip 206. In other words, the conductive via structure 208 is coupled to the TSV structure 210 via the conductive layer 209. The conductive via structure 208 is substantially aligning to the TSV structure 210. Moreover, a trace 207 is formed on the transparent plate 202 and the conductive via structure 208 for electrically connected to the conductive via structure 208. The electronic component 205 is configured on the trace 207 for coupling to the trace 207. The electronic component 205 is for example an active component or a passive component, wherein the active component is a semiconductor integrated circuit (IC), and the passive component includes a capacitor or an inductor. Based-on the through hole structure of the transparent plate 202, the electronic component 205 may be integrated into the transparent plate 202 as a part of the module structure. In other words, without additional placement space for the electronic component, the present invention can integrate multiple electronic components within the module structure. Based-on the conductive via structure 208 and the TSV structure 210, electrical signals of the chip 206 and the electronic component 205 of the module structure 200 may be transmitted to the outside of the module structure via the solder balls 211.

The manufacturing process for the module structure 200 is described as follow. Firstly, a chip 206 is prepared wherein a TSV structure 210 is pre-formed at two-sides of the chip 206. The TSV structure 210 may be formed by utilizing the above-mentioned method or other manufacturing methods. For example, the chip 206 is an image sensor chip (such as CMOS image sensor chip) which has a sensing area 206a on its surface and a contact pad (not shown) formed thereon. Then, a conductive layer 209 is formed on the TSV structure.

Subsequently, a transparent plate 202 stacking process is performed, for example directly disposed on the chip 206. A conductive via structure 208 may be pre-formed at two-sides of the transparent plate 202, or formed after the transparent plate 202 is adhered to the chip 206. In this step, the through hole structure or the conductive via structure 208 is aligning to the conductive layer 209. Then, a trace 207 is formed on the transparent plate 202 and the conductive via structure 208, for electrically connected to the conductive via structure 208. Next, a electronic component 205 is configured on the conductive via structure 208 on the transparent plate 202, for electrically connected to the conductive via structure 208. The vertical position of the configuration of the electronic component 205 does not overlap with the lens 201 and the sensing area 206a to avoid blocking the forwarding light from the lens 201.

Finally, the lens holder 203, which may be a plastic piece or an actuator, is adhered on the transparent plate 202 to complete the module structure 200 of the present invention. In this step, an adhesion layer 204 is formed on the transparent plate 202, and the bottom of the lens holder 203 is adhered on the transparent plate 202 via the adhesion layer 204. The lens 201 is fixed to the lens holder 203 for supporting the lens 201. Moreover, the lens holder 203 may be fixed to the transparent plate 202 for supporting the lens 201. The lens 201 may be optionally disposed above the lens holder 203. The module structure 200 of this embodiment, the transparent plate 202 may be optionally disposed within the lens holder 203, and between the lens 201 and the chip 206. In other words, the lens 201 is substantially aligning to the transparent plate 202 and the chip 206 such that the propagating light can be directly reaching to the sensing area 206a.

In the present invention, the camera module structure can be made without additional substrate.

The advantage of the present invention comprises the active/passive components integrated into the module structure which is no need additional space for component placement.

The foregoing descriptions are preferred embodiments of the present invention. As is understood by a person skilled in the art, the aforementioned preferred embodiments of the present invention are illustrative of the present invention rather than limiting the present invention. The present invention is intended to cover various modifications and similar arrangements included within the spirit and scope of the appended claims, the scope of which should be accorded the broadest interpretation so as to encompass all such modifications and similar structures.

What is claimed is:

1. A wafer level camera module structure, comprising:
a chip with a sensing area, a through silicon via structure formed by passing through from a top surface to a bottom surface of said chip;
a transparent layer, disposed on said chip, with at least one conductive via structure formed therein, and a trace and at least one electronic component formed thereon, wherein said trace is electrically connected to said conductive via structure and said at least one electronic component, and said conductive via structure substantially aligning to said through silicon via structure; and
a lens holder disposed on said transparent layer, and a lens located on said lens holder, substantially aligning to said sensing area.

2. The module structure of claim 1, wherein said lens holder is adhered to said transparent layer via an adhesion layer.

3. The module structure of claim 1, further comprising a conductive layer coupled to said conductive via structure and said through silicon via structure.

4. The module structure of claim 1, further comprising solder balls formed under said through silicon via structure.

5. The module structure of claim 1, wherein said at least one electronic component comprises at least one active component or at least one passive component.

6. The module structure of claim 5, wherein said at least one active component comprises at least one integrated circuit.

7. The module structure of claim 5, wherein said at least one passive component comprises at least one capacitor or at least one inductor.

8. The module structure of claim 1, wherein said chip is an image sensor chip.

9. The module structure of claim 1, wherein a contact pad of said chip is electrically connected to a second trace, wherein said second trace is electrically connected to said through silicon via structure.

10. The module structure of claim 1, wherein said lens holder is a plastic piece or an actuator.
